(19) United States
(12) Patent Application Publication
(10) Pub. No.: US 2017/0045597 A1
(43) Pub. Date: Feb. 16, 2017

(54) MAGNETIC RESONANCE ANTENNA APPARATUS WITH RIGID-FLEXIBLE CONDUCTOR PLATE

(71) Applicants: Daniel Driemel, Oederan (DE); Thomas Kundner, Buckenhof (DE); Jörg Rothard, Litzendorf (DE)

(72) Inventors: Daniel Driemel, Oederan (DE); Thomas Kundner, Buckenhof (DE); Jörg Rothard, Litzendorf (DE)

(21) Appl. No.: 15/235,029

(22) Filed: Aug. 11, 2016

(30) Foreign Application Priority Data
Aug. 12, 2015 (DE) 102015215382.7

(51) Int. Cl. G01R 33/3875; G01R 33/341

(52) U.S. Cl. CPC G01R 33/3875; G01R 33/341

(57) ABSTRACT

A magnetic resonance (MR) antenna apparatus that is arrangeable in and/or on an MR local coil is provided. The MR antenna apparatus is arrangeable in and/or on an MR local coil. The MR antenna apparatus includes at least one rigid-flexible conductor plate with at least one antenna and a plurality of rigid partial conductor plates. The MR antenna apparatus has a form that is adaptable by a relative tilting of the plurality of rigid partial conductor plates.

This application claims the benefit of DE 10 2015 215 382.7, filed on Aug. 12, 2015, which is hereby incorporated by reference in its entirety.

### BACKGROUND

The present embodiments relate to a magnetic resonance (MR) antenna apparatus that is arrangeable in and/or on an MR local coil.

Imaging methods are important aids in medical technology. For example, in clinical sectional imaging, MR tomography is distinguished by high and variable soft tissue contrast levels.

In an MR scan, an examination object (e.g., a patient) is situated at least partially in an examination region of a magnetic resonance apparatus. In this examination region, typically, rapidly switched gradient fields that are generated by a gradient system of the magnetic resonance apparatus are overlaid onto a static basic magnetic field (BO) (e.g., the main magnetic field). In addition, using a high frequency system, high frequency electromagnetic waves are radiated into the examination region. If the frequency of these waves matches the Larmor frequency of the material of the examination object, the waves may be absorbed by atomic nuclei. The atomic nuclei excited thereby emit the absorbed energy again at least partially in the form of magnetic resonance signals. In order to be able to receive the magnetic resonance signals with a high signal-to-noise ratio, typically, MR local coils that are mounted in the immediate vicinity on (anterior to) or under (posterior to) the examination object (e.g., a patient) are used. The MR local coil includes one or more antennae, in which, by the magnetic resonance signals, voltages are induced that are then amplified (e.g., with one or more low-noise pre-amplifiers (MA “low-noise amplifiers”, LNA)) and passed on to a receiving electronic system.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a device that enables an improved arrangement of antennae in a magnetic resonance (MR) local coil is provided.

An MR antenna apparatus is arrangeable in and/or on an MR local coil and includes at least one rigid-flexible conductor plate with at least one antenna (e.g., two antennae) and a plurality of rigid partial conductor plates. The MR antenna apparatus has a form that is adaptable by a relative tilting of the plurality of rigid partial conductor plates.

The at least one antenna is configured to generate electrical and/or magnetic fields and/or to emit and/or receive electromagnetic waves.

The number of rigid partial conductor plates of the plurality of rigid partial conductor plates may be two or more. Each rigid partial conductor plate of the plurality of rigid partial conductor plates may have two parallel flat surfaces and a plurality of end faces. The area of the flat surfaces is typically significantly larger than the area of the plurality of end faces. The rigid partial conductor plates may include stiff material such as, for example, plastics (e.g., fiber-reinforced plastics).

The form of the rigid-flexible conductor plate that may also be designated a “rigid-flex” conductor plate may be adapted, dependent upon the case of use, particularly depending on a body region to be investigated. Due to the flexibility of the rigid-flexible conductor plate, the rigid-flexible conductor plate may follow the body contour. The flexibility is enabled, for example, in that the plurality of rigid partial conductor plates may be tilted relative to one another (e.g., an angle through which the flat surfaces of the plurality of rigid partial conductor plates are angled to one another is adjustable).

For example, at least two of the plurality of rigid-flexible conductor plates may have end faces that are arranged opposing one another and include parallel edges. At least two rigid-flexible conductor plates of the plurality of rigid-flexible conductor plates may be tiltable and/or foldable and/or rotatable and/or pivotable about tilt axes that are oriented parallel to the edges of the opposing end sides and/or are arranged between the opposing end sides.

In one embodiment, the at least one antenna is configured as a shim antenna (e.g., the at least one antenna is configured to generate magnetic fields for homogenizing a basic magnetic field of a magnetic resonance apparatus).

The basic magnetic field in the examination region of a magnetic resonance apparatus may have the greatest possible homogeneity in order to be able to generate images of high quality. During an examination of a living being, due to the anatomical structure of the living being, local distortions of the basic magnetic field may occur in some regions of the body of the living being (e.g., a human body). Such a region is, for example, the head-neck region of most humans. The basic field distortions in some cases are so strong that fat saturation methods that are based on the Lamor frequencies of fat and water differing by 3.4 ppm are caused to fail. As a result, images, in which in some regions, diffeLarmoration of fat and water is no longer possible, so that the diagnostic capacity of the images is negatively affected, are obtained.

Using the at least one antenna, a compensating magnetic field that compensates for any disturbances to the basic magnetic field caused by the examination object (e.g., a human) is generated in order, for example, to enable an unambiguous differentiation between fat and water. A correction of magnetic field inhomogeneities is often also designated shimming, and a device for this purpose is known as a shim.

An antenna of this type for magnetic field correction may therefore be designated a shim antenna or a shim coil. Since the at least one antenna may be arranged locally close to the regions to be corrected, the at least one antenna may also be referred to as a local shim antenna.

Since current flows in closed circuits, for each conductor segment of a local shim antenna, there is also at least one further conductor segment that generates an oppositely oriented magnetic field, so that the desired magnetic field is reduced. Due to the high level of flexibility of the MR antenna apparatus as a result of the use of a rigid-flexible conductor plate, this circumstance may be taken into account, and the at least one antenna may be arranged, firstly, at a small spacing from the examination object and, secondly, in any return conductor regions, at as large a spacing as possible from the examination object.

For example, the at least one antenna configured as a shim antenna is configured to receive electrical signals, such as current signals and/or voltage signals and, based upon these signals, to generate a magnetic field. The electrical signals may be fed, for example, by a magnetic resonance apparatus to the at least one antenna. A shim of this type with adjustment of the currents in shim antennae and/or shim coils may also be designated an active shim.

In one embodiment, the at least one antenna has a sufficiently large number of windings and/or a sufficiently large current carrying capacity in order to be able to generate a sufficiently large magnetic field. In one embodiment, the at least one antenna includes one or more conductor tracks with a layer thickness of, for example, between 0.1 and 0.5 mm or between 0.15 and 0.25 mm. In addition, one or more conductor tracks may consist of copper and/or a copper alloy.

One embodiment of the MR antenna apparatus provides that the MR antenna apparatus has a shaper that fixes the shape of the MR antenna apparatus (e.g., the shaper may be used to hold the MR antenna apparatus in a desired form). An arrangement of the MR antenna apparatus optimally adapted to the geometry of the examination object (e.g., the plurality of rigid partial conductor plates) may thus be achieved. In addition, by the shaper, the arrangement of a rigid-flexible conductor plate in and/or on an MR local coil may be facilitated (e.g., if still to be brought into shape). In addition, a shaper reduces the risk that any components placed onto the rigid-flexible conductor plate are damaged by the necessary handling of the MR antenna apparatus.

In one embodiment, the shaper has two lateral walls that may also be designated side plates. The lateral walls may be arranged, for example, parallel to one another. The lateral walls may be constructed symmetrical in order to allow bilateral use.

In one embodiment, the shaper includes a connecting member that is configured to connect the two lateral walls to one another. In addition, the connecting member may act as a spacer between the lateral walls. In order to increase the torsional stiffness of the MR antenna apparatus, the connecting member is advantageously configured angled. In one embodiment, ribs may be mounted on the connecting member for stiffening.

In one embodiment, the shaper has a snap connection that is configured to connect the connecting member to at least one of the two lateral walls. The snap connection enables easy assembly between the lateral walls and the connecting member. Optionally, the snap connection may include oppositely oriented snap hooks (e.g., double oppositely oriented snap hooks) in order to increase the connecting reliability on torsion of the lateral walls.

The snap hooks may have a cross-sectional form that tapers acutely to a hook end and, at a certain spacing from the hook end, has a shoulder that latches into a receiving apparatus of the lateral wall (e.g., a recess such as an aperture and/or slot). Snap hooks are, for example, oppositely oriented if shoulders of the snap hooks are at least partially oriented in different (e.g., opposite) directions.

In one embodiment, the lateral walls have grooves that are configured to accommodate the plurality of rigid conductor plates at least partially (e.g., a connection of the rigid-flexible conductor plates to the lateral walls by grooves that embrace the rigid partial conductor plates).

In addition, the shaper may be at least partially (e.g., completely) configured as MR-inactive (e.g., the materials used do not emit any disruptive high-frequency signal). Plastics such as polyamides (PA), polycarbonates (PC) and/or polybutylene terephthalate (PBT) may be used for this.

An embodiment of the MR antenna apparatus provides that the at least one MR antenna apparatus includes a plurality of circuits (e.g., component-equipped circuits that are arranged on one side on the rigid-flexible conductor plate), where all the circuits are arranged on one side on the rigid-flexible conductor plate (e.g., the rigid-flexible conductor plate includes a first side (an underside) and a second side (an upper side). The arrangement of the circuits is carried out only on one of the two sides, but not on both sides.

This one-sided component equipping of the rigid-flexible conductor plate enables an economical and automatable production. Such circuits may be inserted, for example, so that in the case of the use of the at least one antenna as a shim antenna, the at least one antenna does not form a resonant structure in the region of the Larmor frequency.

A further embodiment provides that the at least one MR antenna apparatus includes a plurality of circuits (e.g., circuits equipped with components that are arranged on the rigid-flexible conductor plate), where all the circuits are arranged only in the regions that are covered by the plurality of rigid partial conductor plates (e.g., the rigid partial conductor plates serve as carriers of the plurality of circuits). Using the exclusive arrangement of the circuits in the rigid regions of the rigid partial conductor plates, the mechanical stability of the component-equipped circuits may be increased.

In one embodiment, the at least one rigid-flexible conductor plate has at least one flexible partial conductor plate that connects the plurality of rigid partial conductor plates to one another. Using the connection of the at least one flexible partial conductor plate and the plurality of rigid partial conductor plates, a bendable overall arrangement may be achieved (e.g., at the connecting sites between two of the plurality of rigid partial conductor plates, bending regions that impart flexibility to the MR antenna apparatus form). This flexibility of the MR antenna apparatus in the bending regions is determined by the flexibility of the at least one flexible partial conductor plate. The at least one flexible partial conductor plate may include a film (e.g., a plastics film that contains polyimides (PI) and/or liquid crystal polymers (LCP)).

The combination of the at least one flexible partial conductor plate with the plurality of rigid partial conductor plates may take place, for example, by areal and/or spot-wise cementing with adhesive and/or adhesive film.

The at least one flexible partial conductor plate at least partially covers each rigid partial conductor plate of the plurality of rigid partial conductor plates. By this, a continuous uninterrupted surface may be provided for the at least one antenna of the MR antenna apparatus. For example, one antenna of the at least one antenna may be arranged on this continuous surface that extends over a region that includes more than one rigid partial conductor plate of the plurality of rigid partial conductor plates.

One embodiment provides that the MR antenna apparatus includes at least one first antenna and at least one second antenna. The at least one first antenna includes at least one first conductor track that is predominantly (e.g., at least 80 percent) arranged on a first surface of the rigid-flexible conductor plate. The at least one second antenna includes at least one second conductor track that is predominantly (e.g., at least 80 percent) arranged on a second surface of the rigid-flexible conductor track. The first surface and the second surface are situated on opposite sides of the rigid-flexible conductor plate.

In one embodiment, the at least one first conductor track is not more than 20 percent arranged on the second surface of the rigid-flexible conductor plate, and/or the at least one second conductor track is not more than 20 percent arranged on the first surface of the rigid-flexible conductor plate.

Due to the arrangement of the antennae on different surfaces, the antennae may be spatially separated. The spacing between the first surface and the second surface may amount to between 1.5 and 3 mm.

In one embodiment, the first surface is included by at least one surface of the at least one flexible partial conductor plate and the second surface is included by a plurality of surfaces of the plurality of rigid partial conductor plates.

The first surface is therefore included by one (e.g., exterior) surface of the at least one flexible partial conductor plate, and the second surface is, for example, included by a plurality of (e.g., exterior) surfaces of the plurality of rigid partial conductor plates. The surfaces mentioned are therefore not adhesive areas by which the at least one flexible partial conductor plate is connected to the plurality of partial conductor plates.

The spacing is substantially determined by the total of the layer thicknesses of the at least one flexible partial conductor plate, the plurality of rigid partial conductor plates, and any adhesive layers between the plurality of rigid partial conductor plates and the at least one flexible partial conductor plate.

The second surface that is included by a plurality of surfaces of the plurality of rigid partial conductor plates typically has at least one interruption (e.g., the rigid partial conductor plates are separated from one another by defined spacings that, when combined, result in bending regions).

For example, all circuits (e.g., component-equipped circuits) may be arranged on the side of the first surface in order to enable simple equipping of the circuits.

One embodiment provides that the at least one flexible partial conductor plate for arranging at least one circuit of the plurality of circuits (e.g., component-equipped circuits) includes at least one cut-out. By this, the plurality of circuits may be arranged closer to any conductor tracks that are arranged on a surface of the plurality of rigid partial conductor plates.

An MR local coil that includes an MR antenna apparatus according to one or more of the present embodiments is also provided. The advantages of the MR local coil correspond substantially to the advantages of the MR antenna apparatus, which are described in detail above.

In the event that the at least one antenna is used as a shim antenna, the at least one antenna may be arranged locally close to the sites at which disturbances caused by the examination object arise, since these disturbances are typically locally limited. These shim antennae may be integrated in a local coil adapted for the relevant body region.

For example, the MR local coil may include a receptacle surface for accommodating an examination object and an MR antenna apparatus with a rigid-flexible conductor plate. The form of the rigid-flexible conductor plate and the arrangement of the rigid-flexible conductor plate are configured on and/or in the MR local coil, partially to create a smallest possible spacing between the receptacle surface and the rigid-flexible conductor plate and partially to create a largest possible spacing between the receptacle surface and the rigid-flexible conductor plate.

The receptacle surface may be, for example, an area into which the examination object (e.g., a body part) is positionable during the magnetic resonance examination (e.g., a lying surface and/or support surface in which a head of a human may be inserted).

Thereby, for example, the spacing between the receptacle surface and the at least one antenna of the MR antenna apparatus is partially as small as possible and partially as large as possible (e.g., there are regions in which the spacing is as large as possible and other regions in which the spacing is as small as possible).

The smallest possible spacing may be at least two times (e.g., at least three times or at least four times) smaller than the largest possible spacing. In one embodiment, the largest possible spacing is at least 3 cm (e.g., at least 5 cm or at least 10 cm).

The ratio of the spacings and thus also the effectiveness of the at least one antenna as a possible shim antenna is typically limited by the installation space available in and/or on the MR local coil. As described above, by this, the effect of any disturbing currents on the resultant magnetic field may be reduced.

For example, the MR local coil is a head-neck-MR local coil (e.g., an MR local coil that is usable for examining a head and/or a neck of a human body). A shim antenna for correcting magnetic field inhomogeneities may be effectively utilized herein, since an increase of the basic magnetic field takes place in the shoulder region and a reduction of the basic magnetic field takes place in the head-neck region.

The head-neck-MR local coil may be configured, for example, tiltable so that the flexibility of the MR antenna arrangement is particularly advantageous.

One or more of the present embodiments may also be used on other body regions and/or MR local coil types, such as ankle coils, wrist coils, knee coils, chest coils, shoulder coils, head coils, neck coils, and head-neck coils.

In one embodiment, the MR antenna apparatus is arranged in a neck region of the head-neck-MR local coil in order to compensate in this magnetic field for disturbances in the basic magnetic field, since particularly severe magnetic field inhomogeneities occur here. In one embodiment, the head-neck-MR local coil has an anterior coil unit and a posterior coil unit, where the MR antenna apparatus is arranged at the posterior coil unit.

In addition, two shim antennae may be integrated into the head-neck-MR local coil since with that, a corrective compensating magnetic field may be generated particularly effectively.

In one embodiment, the MR local coil includes at least one alignment unit (e.g., a dome; a screw-on dome). In addition, the MR antenna apparatus includes at least one shaper (e.g., with a connecting member). An arrangement of the MR antenna apparatus at the MR local coil takes place only by an arrangement of the at least one alignment unit at the shaper (e.g., at the connecting member of the shaper).

By the fastening of the MR antenna apparatus via alignment units that may only be mounted on the shaper (e.g., on the connecting member of the shaper), it may be prevented that a force is exerted on the rigid-flexible conductor plate of the MR antenna apparatus. In this way, the risk of possible damage to the relatively sensitive rigid-flexible conductor plate may be reduced.

A magnetic resonance apparatus that includes at least one MR local coil according to one or more of the present embodiments may also be provided. The advantages of the MR local coil correspond substantially to the advantages of the MR antenna apparatus and the MR local coil, which are described in detail above.

### BRIEF DESCRIPTION OF THE DRAWINGS

Parts that correspond to one another are provided with the same reference signs in all the drawings.

FIG. 1 is a schematic representation of one embodiment of a magnetic resonance apparatus;

FIG. 2 is a representation of one embodiment of a head-neck-MR coil;

FIG. 3 is a representation of one embodiment of an MR antenna apparatus;

FIG. 4 is a representation of a front side of one embodiment of a rigid-flexible conductor plate;

FIG. 5 is a representation of a rear side of one embodiment of a rigid-flexible conductor plate;

FIG. 6 is a sectional view of a part of one embodiment of the rigid-flexible conductor plate;

FIG. 7 is a representation of one embodiment of a shaper;

FIG. 8 is a detail representation of one embodiment of a shaper; and

FIG. 9 is a sectional view of one embodiment of a head-neck-MR coil.

### DETAILED DESCRIPTION

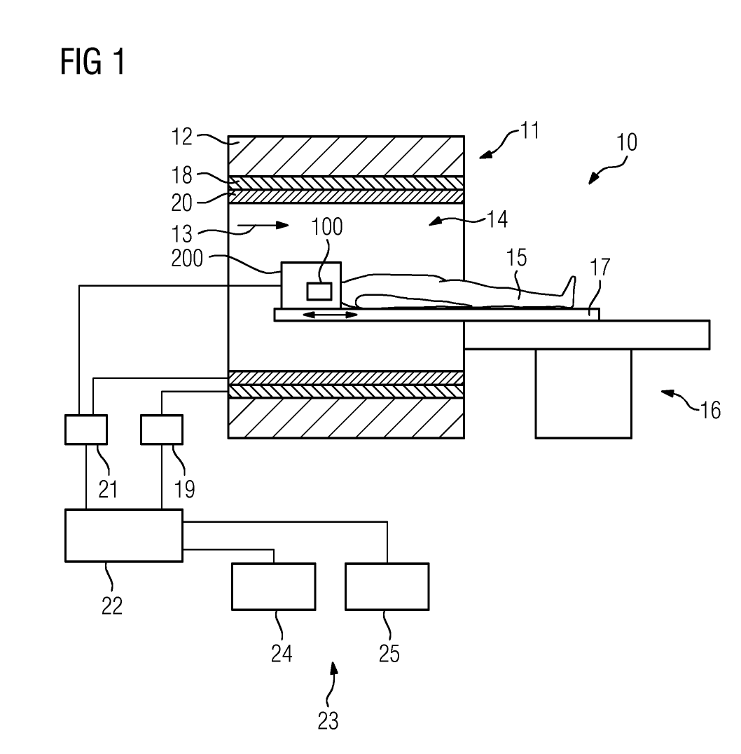

FIG. 1 shows schematically a magnetic resonance apparatus 10. The magnetic resonance apparatus 10 includes a magnet unit 11 that includes a superconducting main magnet 12 for generating a strong and homogeneous (e.g., particularly in a scan region) basic magnetic field 13. In addition, the magnetic resonance apparatus 10 includes a patient accommodating region 14 to accommodate a patient 15. In the present exemplary embodiment, the patient accommodating region 14 is configured cylindrical and is surrounded cylindrically in a peripheral direction by the magnet unit 11. A configuration of the patient accommodating region 14 deviating therefrom may also be provided. The patient 15 may be pushed by a patient support apparatus 16 of the magnetic resonance apparatus 10 into the patient accommodating region 14. For this purpose, the patient support apparatus 16 includes a patient table 17 that is configured to be movable within the patient accommodating region 14.

The magnet unit 11 also includes a gradient coil unit 18 for generating magnetic field gradients that are used for position encoding during imaging. The gradient coil unit 18 is controlled by a gradient control unit 19 of the magnetic resonance apparatus 10. The magnet unit 11 further includes a high frequency antenna unit 20 that is configured in the present exemplary embodiment as a body coil that is firmly integrated into the magnetic resonance apparatus 10. The high frequency antenna unit 20 is configured to excite atomic nuclei situated in the main magnetic field 13 generated by the main magnet 12. The high frequency antenna unit 20 is controlled by a high frequency antenna control unit 21 of the magnetic resonance apparatus 10 and radiates HF magnetic resonance sequences into an examination space that is substantially formed by a patient accommodating region 14 of the magnetic resonance apparatus 10. The high frequency antenna unit 20 is also configured for the receiving of magnetic resonance signals.

The magnetic resonance signals may be received, for example, by an MR local coil 200 that is connected to the high frequency antenna control unit 21. In this example, the MR local coil 200 is arranged in the head-neck region of the patient 15 (e.g., the MR local coil 200 is a head-neck-MR local coil). The MR local coil 200 includes an MR antenna apparatus 100. The MR antenna apparatus 100 includes at least one rigid-flexible conductor plate with at least one antenna and a plurality of rigid partial conductor plates. The at least one antenna may be configured, for example, to generate magnetic fields for homogenizing the basic magnetic field 13 of the magnetic resonance apparatus 10. For example, in the head-neck region, the basic magnetic field 13 is often disrupted by the patient 15.

For controlling the main magnet 12, the gradient control unit 19 has a system control unit 22, and for controlling the high frequency antenna control unit 21, the magnetic resonance apparatus 10 has the system control unit 22. The system control unit 22 centrally controls the magnetic resonance apparatus 10 (e.g., the execution of a pre-determined imaging gradient echo sequence). The system control unit 22 includes an evaluation unit (not disclosed in detail) for evaluating medical image data that is acquired during the magnetic resonance examination. The magnetic resonance apparatus 10 also includes a user interface 23 that is connected to the system control unit 22. Control information such as, for example, imaging parameters and reconstructed magnetic resonance images may be displayed on a display unit 24 (e.g., on at least one monitor) of the user interface 23 for medical operating personnel. In addition, the user interface 23 has an input unit 25 by which information and/or parameters may be input by the medical operating personnel during a scanning procedure.

The magnetic resonance apparatus 10 disclosed in the present exemplary embodiment may include further components that magnetic resonance apparatuses typically have. A general mode of operation of a magnetic resonance apparatus 10 is also known to a person skilled in the art, so that a detailed description of the general components is omitted.

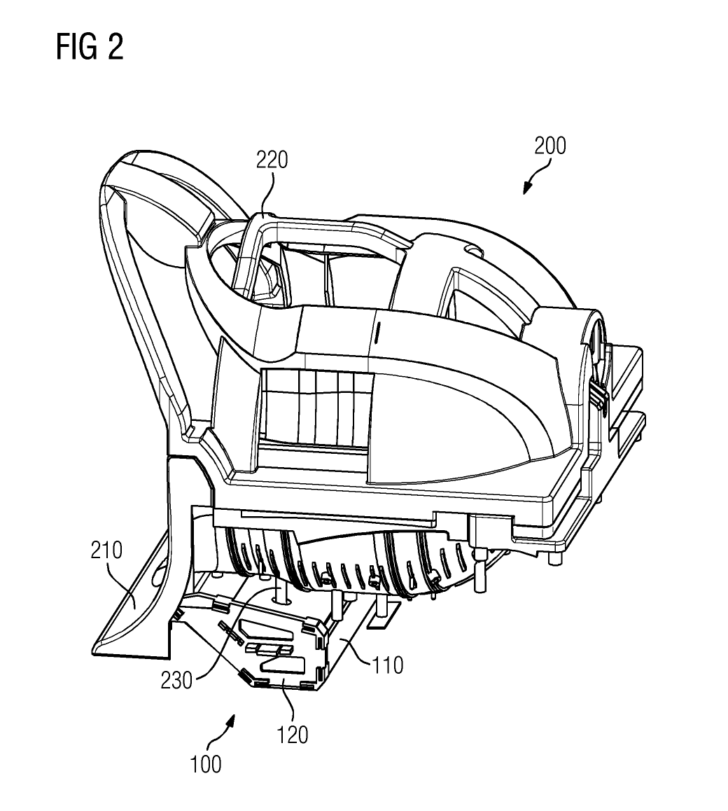

FIG. 2 shows schematically one embodiment of a head-neck-MR local coil 200. For the sake of clarity, a side covering has been omitted in FIG. 2. The head-neck-MR coil includes as the upper part, an anterior coil unit 220 and as the lower part, a posterior coil unit 210. Arranged in the neck region of the posterior coil unit 210 is an MR antenna apparatus 100 that includes a rigid-flexible conductor plate 110, the form of which is fixed by a shaper 120.

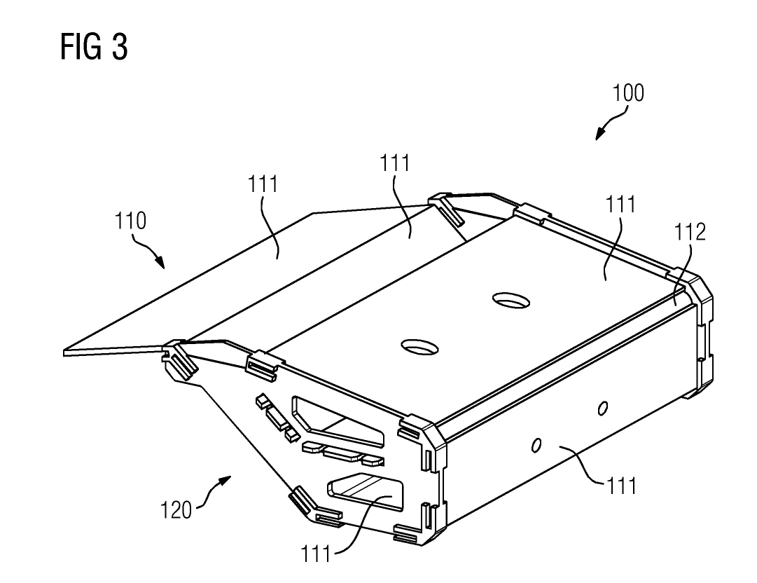

FIG. 3 shows that the MR antenna apparatus 100 includes a rigid-flexible conductor plate 110 with a plurality of (e.g., five) rigid partial conductor plates 111 and a flexible partial conductor plate 112. The rigid partial conductor plates 111 have a high mechanical stability, whereas the flexible partial conductor plates 112 enable a high degree of mechanical flexibility of the overall arrangement.

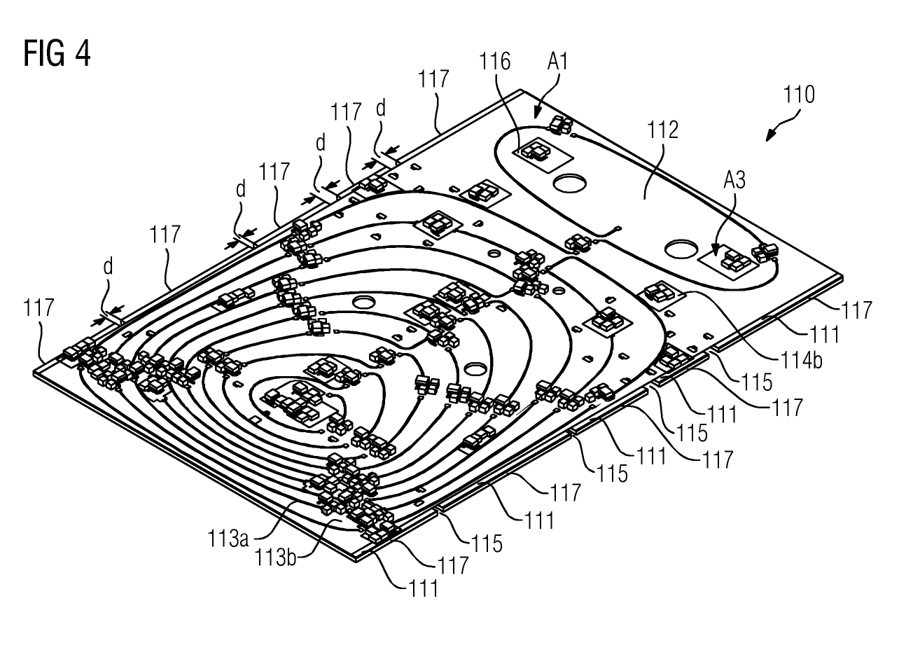

FIG. 4 shows one embodiment of an unfolded representation of a front side of the rigid-flexible conductor plate 110 looking toward the flexible partial conductor plate 112 on which the five rigid partial conductor plates 111 are arranged, so that the flexible partial conductor plate 112 connects the five rigid partial conductor plates 111 to one another. The rigid conductor plate region is subdivided into five rigid partial regions. More or fewer, but at least two, rigid partial regions may be provided.

The five rigid partial conductor plates 111 are spaced at spacings d. These defined spacings may be set during manufacture by the use of temporary connecting webs that are later removed. The gaps arising therefrom are bending regions 115 of the rigid-flexible conductor plate 110. By bending in these bending regions 115 (e.g., through tilting of the plurality of rigid partial conductor plates 111), the MR antenna apparatus 100 may be brought into a desired form, as shown, for example, in FIG. 3.

The surface of the flexible partial conductor plate 112 visible in FIG. 4 is a first surface A1 of the rigid-flexible conductor plate 110 on which a conductor track 113a and a plurality of circuits 113b, 114b (e.g., component-equipped circuits) are arranged. In order to improve the clarity, the circuits 113b, 114b and the conductor track 113a are provided with reference signs only by way of example. The circuits 113b are arranged in the course of the conductor track 113a. The conductor track 113a and the circuits 113b are included by a first antenna.

The flexible partial conductor plate 112 has cut-outs 116. In these cut-outs 116 and at longitudinal ends 117 of the rigid partial conductor plates 111, the rigid partial conductor plates 111 are not covered by the flexible partial conductor plates 112, so that at these sites, the surface A3 of the five rigid partial conductor plates 111 is visible. The circuits 114b are arranged in the cut-outs 116.

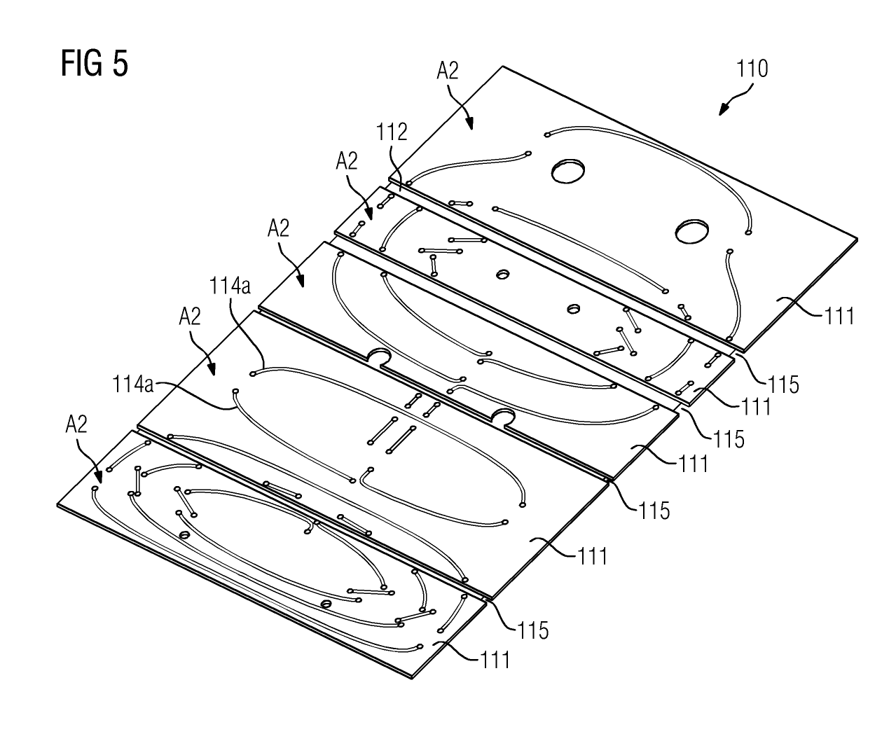

FIG. 5 shows an unfolded representation of a rear side of the rigid-flexible conductor plate 110 with a view toward the rigid partial conductor plates 111. The surface of the five rigid partial conductor plates 111 visible in FIG. 5 is a second surface A2 of the rigid-flexible conductor plate 110 on which the majority of the conductor track 114a is arranged. The conductor track 114a is included by a second antenna. Situated in the bending regions is a small portion of the conductor track 114a on the first surface A1, as shown in FIG. 4. The arrangement of this small part of the conductor track 114a on the flexible partial conductor plate 112 is provided to be able to guide the conductor track 114a over the flexible bending regions 115.

By vias through the rigid partial conductor plates 111 and due to the flexible partial conductor plate, the parts of the conductor tracks 114a that are arranged on the first surface A1 shown in FIG. 4 are connected to the parts of the conductor track 114a that are arranged on the second surface. Similarly, by vias, the conductor track 114a is connected to the circuits 114b, which are also shown in FIG. 4, that lie on the course of the conductor track 114a and are also included by the second antenna. A via is thus a vertical electrical connection between the conductor track planes of a conductor plate. The connection is mostly realized by an internally metalized bore in the support material of the conductor plate. Rivets and pins may also be used.

The conductor tracks may have a layer thickness of between 0.15 and 0.25 mm. If required, the layer thickness may be brought, for example, galvanically and/or chemically to a desired value.

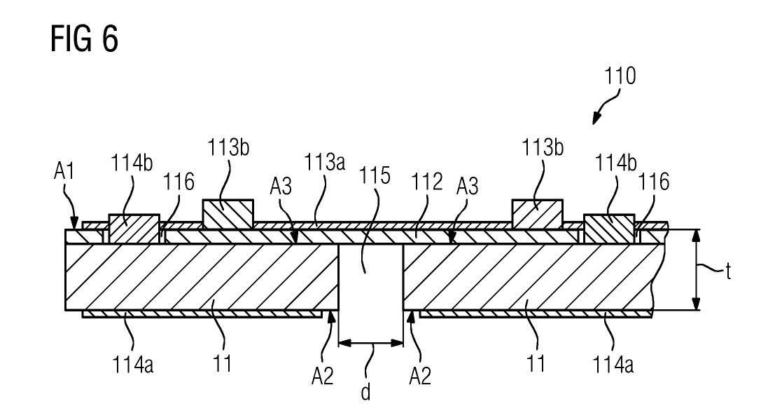

FIG. 6 shows schematically a sectional view of one embodiment of a part of the rigid-flexible conductor plate 110. Through the arrangement of the conductor tracks on surfaces A1, A2 that lie on opposite sides of the rigid-flexible conductor plate 110, the conductor tracks 113a, 114a and thus the antennae have a spacing t that may lie between 1.5 and 3 mm. All circuits 114a, 115a of the MR antenna apparatus 100 are arranged on one side on the rigid-flexible conductor plate 110 (e.g., on the front side of the rigid-flexible conductor plate 110 on the surfaces A1 and A3). The circuits 114a, 115a are arranged only in regions that are covered by the plurality of rigid partial conductor plates 111, so that the five rigid partial conductor plates 111 are used as a carrier of the circuits 114a, 115a. Circuits 114a, 115a equipped with the components may not be placed in the bending regions 115 since due to a bending of the carrier, the components themselves and corresponding solder connections would be damaged.

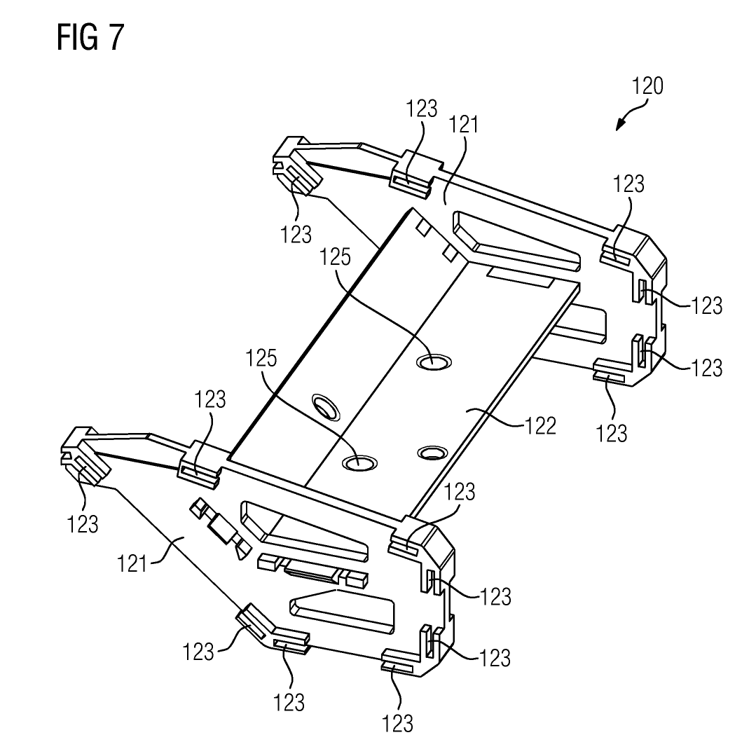

The shaper 120 is shown in FIG. 7. The shaper 120 includes two lateral walls 121 that are constructed symmetrical in one dimension (e.g., each of the lateral walls has a central plane that is also a symmetry plane of the lateral wall). Thus, the same component may be used twice. The lateral walls 120 are fastened to one another via the connecting member 122. The lateral walls 121 have integrated grooves 123 that engage in the rigid partial conductor plates, as shown in FIG. 3. So that the groove 123 may be unambiguously dimensioned, the groove 123 grasps only the rigid partial conductor plates 111. As already shown in FIG. 4, the longitudinal ends 117 of the rigid partial conductor plates 111 are kept free from the flexible partial conductor plate 112. The rigid-flexible conductor plate 110 is therefore configured so that the partial conductor plates 111 project laterally beyond the flexible partial conductor plate 112 (e.g., in that the flexible partial conductor plate 111 is set back in the region of the grooves 123 by the dimension of the groove depth in the lateral wall 121 relative to the rigid partial conductor plates 111).

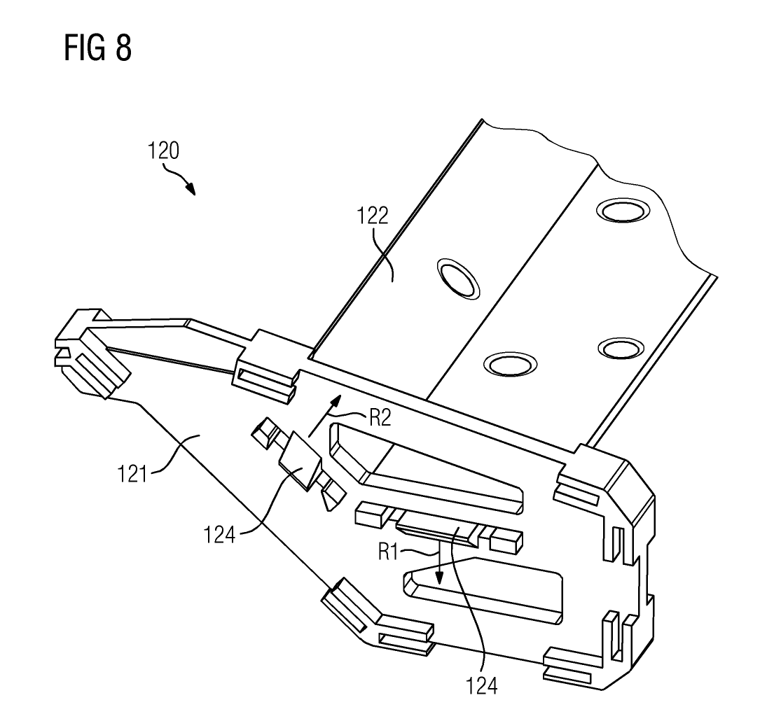

As shown in detail in FIG. 8, the connecting member 122 is fastened by snap connections in the lateral wall 121. For this purpose, the connecting member 122 includes at each end two snap hooks 124 that may enter into a connection with the lateral walls 121. The snap hooks 124 are configured mutually opposed in order to enhance security (e.g., against torsion; one hook points in a first direction R1, and the other hook points in another direction R2). The connecting member 122 is configured angled in order to counteract a possible torsion of the lateral walls 121 as much as possible.

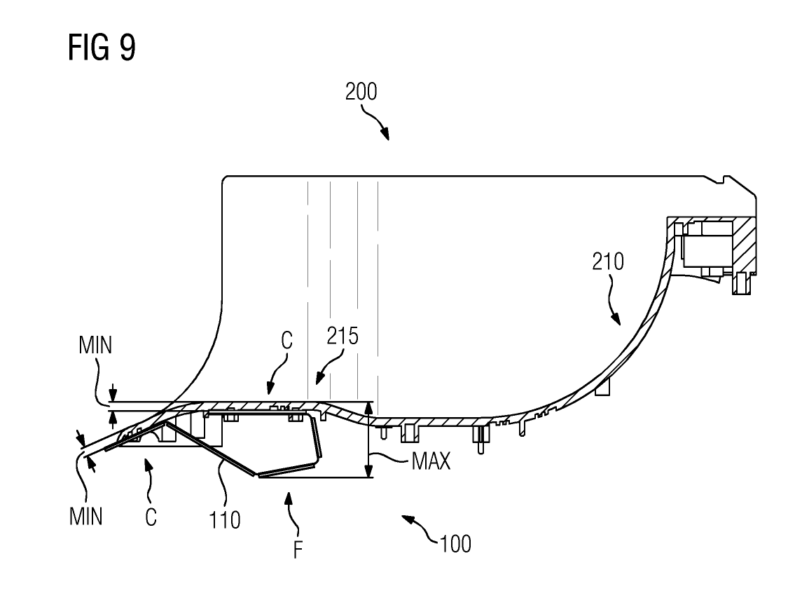

FIG. 9 illustrates an advantage that results from the flexibility of the MR antenna apparatus. The form of the rigid-flexible conductor plate 110 and the arrangement of the rigid-flexible conductor plate 110 in the MR local coil are configured so that in the regions C, the smallest possible spacing MIN between a receptacle surface 215 and the rigid-flexible conductor plate is provided, and in other regions F, the largest possible spacing MAX is provided. Herein, 2MIN≦MAX may apply. In one embodiment, 3MIN≦MAX applies. In another embodiment, 4MIN≦MAX applies. In one embodiment, MAX≧3 cm applies (e.g., MAX≧5 cm or at least MAX≧10 cm).

The head of the patient 15 is positionable in the receptacle surface 215. In the widely spaced regions F, conductor members of the first and/or second antenna that attenuate a desired magnetic field may advantageously be arranged so that the attenuating effect of the conductor members is minimized as far as possible by the large spacing MAX.

In FIG. 2, alignment units 230 (e.g., screw-on domes) are shown. Using the alignment units 230, the MR antenna apparatus 100 is arranged and/or fastened in the MR local coil 200 (e.g., at the posterior coil unit 210). The fastening may be provided by screw connections. The alignment units 230 are mounted only on the shaper 120 (e.g., on the connecting member 122 that has cut-outs 125 that are visible in FIG. 7). By this, a direct force application onto the rigid-flexible conductor plate 110 may be avoided.

The shaper 120 may thus easily be mounted on the rigid-flexible conductor plate 110. The connecting member 122 latches into one of the two lateral walls 121. Then, the rigid-flexible conductor plate 110 is bent, and the rigid partial conductor plates 111 are inserted into the grooves 123 of this lateral wall 121. The second lateral wall 121 is positioned, and the rigid partial conductor plates 111 are brought into conformity again with the grooves 123 and locked in. The MR antenna apparatus 100 may thus be further processed without mechanical loading of the rigid-flexible conductor plate 110. Using two alignment units on the connecting member 122, the assembly may be fastened in the posterior coil unit 210.

Although the invention has been illustrated and described in detail based on the exemplary embodiments, the invention is not restricted by the examples given. Other variations may be derived therefrom by a person skilled in the art without departing from the protective scope of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A magnetic resonance (MR) antenna apparatus that is arrangeable in, on, or in and on an MR local coil, the MR antenna apparatus comprising:
at least one rigid-flexible conductor plate comprising at least one antenna and a plurality of rigid partial conductor plates,
wherein the MR antenna apparatus has a form that is adaptable by a relative tilting of the plurality of rigid partial conductor plates.

2. The MR antenna apparatus of claim 1, wherein the at least one antenna is configured as a shim antenna.

3. The MR antenna apparatus of claim 1, wherein the MR antenna apparatus comprises a shaper that fixes a shape of the MR antenna apparatus.

4. The MR antenna apparatus of claim 3, wherein the shaper comprises two lateral walls.

5. The MR antenna apparatus of claim 4, wherein the shaper comprises a connecting member configured to connect the two lateral walls to one another.

6. The MR antenna apparatus of claim 5, wherein the connecting member is configured angled.

7. The MR antenna apparatus of claim 5, wherein the shaper comprises a snap connection that is configured to connect the connecting member to at least one of the two lateral walls.

8. The MR antenna apparatus of claim 7, wherein the snap connection comprises oppositely oriented snap hooks.

9. The MR antenna apparatus of claim 4, wherein the two lateral walls comprise grooves that are configured to accommodate the plurality of rigid conductor plates at least partially.

10. The MR antenna apparatus of claim 1, further comprising a plurality of circuits that are arranged on the at least one rigid-flexible conductor plate,
wherein all circuits of the plurality of circuits are arranged on one side on the at least one rigid-flexible conductor plate.

11. The MR antenna apparatus of claim 1, further comprising a plurality of circuits that are arranged on the at least one rigid-flexible conductor plate,
wherein all circuits of the plurality of circuits are arranged only in regions that are covered by the plurality of rigid partial conductor plates.

12. The MR antenna apparatus of claim 1, wherein the at least one rigid-flexible conductor plate comprises at least one flexible partial conductor plate that connects the plurality of rigid partial conductor plates to one another.

13. The MR antenna apparatus of claim 12, wherein the at least one flexible partial conductor plate at least partially covers each rigid partial conductor plate of the plurality of rigid partial conductor plates.

14. The MR antenna apparatus of claim 12, further comprising at least one first antenna and at least one second antenna,
wherein the at least one first antenna comprises at least one first conductor track that is predominantly arranged on a first surface of the at least one rigid-flexible conductor plate,
wherein the at least one second antenna comprises at least one second conductor track that is predominantly arranged on a second surface of the at least one rigid-flexible conductor plate, and
wherein the first surface and the second surface are on opposite sides of the at least one rigid-flexible conductor plate.

15. The MR antenna apparatus of claim 14, wherein the first surface is included by at least one surface of the at least one flexible partial conductor plate, and the second surface is included by a plurality of surfaces of the plurality of rigid partial conductor plates.

16. The MR antenna apparatus of claim 12, further comprising a plurality of circuits that are arranged on the at least one rigid-flexible conductor plate,
wherein for arranging at least one circuit of the plurality of circuits, the at least one flexible partial conductor plate comprises at least one cut-out.

17. A magnetic resonance (MR) local coil comprising:
an MR antenna apparatus that is arrangeable in, on, or in and on the MR local coil, the MR antenna apparatus comprising:
at least one rigid-flexible conductor plate comprising at least one antenna and a plurality of rigid partial conductor plates,
wherein the MR antenna apparatus has a form that is adaptable by a relative tilting of the plurality of rigid partial conductor plates.

18. The MR local coil of claim 17, further comprising a receptacle surface for accommodating an examination object,
wherein the form of a rigid-flexible conductor plate of the at least one rigid-flexible conductor plate and the arrangement of the rigid-flexible conductor plate are configured on, in, or on and in the MR local coil to partially minimize spacing between the receptacle surface and the rigid-flexible conductor plate and to partially maximize spacing between the receptacle surface and the rigid-flexible conductor plate.

19. The MR local coil of claim 17, wherein the MR local coil is a head-neck-MR local coil.

20. The MR local coil of claim 19, wherein the MR antenna apparatus is arranged in a neck region of the head-neck-MR local coil.

21. The MR local coil of claim 17, wherein the MR local coil comprises at least one alignment unit,
wherein the MR antenna apparatus comprises at least one shaper, and
wherein an arrangement of the MR antenna apparatus at the MR local coil takes place by an arrangement of the at least one alignment unit at the shaper.

22. A magnetic resonance apparatus comprising:
at least one MR local coil comprising:
an MR antenna apparatus that is arrangeable in, on, or in and on the MR local coil, the MR antenna apparatus comprising:
at least one rigid-flexible conductor plate comprising at least one antenna and a plurality of rigid partial conductor plates,
wherein the MR antenna apparatus has a form that is adaptable by a relative tilting of the plurality of rigid partial conductor plates.
